(19) United States
(12) Patent Application Publication
(10) Pub. No.: US 2011/0297976 A1
(43) Pub. Date: Dec. 8, 2011

(54) Illumination Module

(75) Inventors: Tzu-Hao Chao, New Taipei City (TW); Po-Chih Wang, New Taipei City (TW)

(73) Assignees: EVERLIGHT ELECTRONICS CO., LTD., New Taipei City (TW); EVERLIGHT YI-GUANG TECHNOLOGY (SHANGHAI) LTD., Shanghai (CN)

(21) Appl. No.: 13/114,942

(22) Filed: May 24, 2011

(30) Foreign Application Priority Data
Jun. 4, 2010 (TW) 099118188

(51) Int. Cl. H01L 33/08

(52) U.S. Cl. 257/89; 257/E33.005

(57) ABSTRACT

An illumination module including a substrate and a plurality of first and second LED chips is provided. The substrate has a plurality of device bonding areas, and each of device bonding areas has two sub-device bonding areas. Each sub-device bonding area has a first, second, and common route. The first routes surround the outer peripheries of each device bonding area. The second routes are located between the two sub-device bonding areas. The common routes are located between the first and second routes. The first LED chips located at the common routes are electrically connected to each other. The second LED chips located at the first and second routes respectly are electrically connected to each other.

### CROSS-REFERENCE TO RELATED APPLICATIONS

This application claims priority to Taiwan Patent Application No. 099118188, entitled “Illumination Module”, filed on Jun. 4, 2010, which is herein incorporated in its entirety by reference.

### BACKGROUND

1. Technical Field

The present disclosure relates generally to an illumination module, and more particularly to an illumination module adopting a light emitting diode (LED) chip as a light emitting device.

2. Description of Related Art

Due to the longer lifespan and the lower electricity consumption of the light emitting diodes (LEDs), fluorescent lamps and incandescent bulbs are gradually being replaced with LEDs in some fields of applications, such as a scanning light source which requires fast response speed, a backlight source of a liquid crystal display (LCD) device, a front light source providing dashboard illumination for a car, traffic signs, large electronic display bulletins, and general illumination devices.

Generally speaking, in a control circuit of an LED, typically an alternating current (AC) voltage is first converted to a direct current (DC) voltage or current, and then the stabilized DC voltage or current is used to control a light source brightness of the LED. That is, an AC-DC converter is typically embedded in the control circuit of a conventional LED, or alternatively, electronic components such as an inverter, a rectifier, a filter, or a voltage regulator must be included for control with AC power from an outlet. However, in these implementations, not only a physical area of the control circuit of the LED is increased, the LED is further limited in the ease of applicability.

Moreover, a large amount of heat is produced when the LED emits a high brightness light. If the heat cannot be readily dissipated and accumulates inside the LED, a temperature of the LED would continually rise. Consequently, the overheating may cause the LED to have a reduced brightness and usable lifespan, or even cause permanent damage to the LED. Therefore, an issue of LED heat dissipation has become critically important for manufacturers of illumination modules adopting the LED as the light emitting device.

### SUMMARY

An aspect of the present disclosure provides an illumination module capable of reducing a number of the electronic components (e.g., inverters, rectifiers, filters, or voltage regulators) required and reducing manufacturing costs.

An aspect of the present disclosure provides an illumination module capable of having a preferred heat dissipating capacity and a preferred light emitting efficiency.

An aspect of the present disclosure provides an illumination module charged by alternating current (AC) power including a substrate, a plurality of first light emitting diode (LED) chips, and a plurality of second LED chips. The substrate has a plurality of device bonding areas. Each of the device bonding areas has two sub-device bonding areas. Each of the sub-device bonding areas has a first route, a second route, and a common route. The first routes surround the outer peripheries of each device bonding areas. The second routes are located between the two sub-device bonding areas. Moreover, the common routes are located between the first routes and the second routes. The first LED chips are located at the common routes and electrically connected to each other. The second LED chips are located at the first routes and the second routes respectively electrically connected to each other.

According to an embodiment of the present disclosure, the illumination module charged by alternating current (AC) power further includes a plurality of Zener diode chips respectively disposed inside the device bonding areas. The Zener diode chips are respectively located at the first routes or at the second routes inside the sub-device bonding areas.

According to an embodiment of the present disclosure, the illumination module charged by alternating current (AC) power further includes an adhesive layer disposed between the substrate and the first LED chips and between the substrate and the second LED chips.

According to an embodiment of the present disclosure, the illumination module charged by alternating current (AC) power further includes a plurality of first bonding pads and a plurality of second bonding pads. Each of the device bonding areas corresponds to a first bonding pad and a second bonding pad, and the first bonding pads and the second bonding pads are respectively located between the first routes and the second routes of the sub-device bonding areas and connected to the first routes and the second routes.

According to an embodiment of the present disclosure, the illumination module charged by alternating current (AC) power further includes a plurality of bridge lines respectively disposed between any two adjacent device bonding areas, and the bridge lines are extended from the second bonding pad inside one of the device bonding areas to the first bonding pad inside another one of the device bonding areas adjacent to the second bonding pad.

According to an embodiment of the present disclosure, the bridging lines respectively bridge the corresponding first bonding pads and the corresponding second bonding pads, and the remaining first bonding pad and the second bonding pad located at two ends are respectively electrically connected to an AC power supply through a plurality of external lead lines, so as to form a series loop serially connecting all of the device bonding areas.

According to an embodiment of the present disclosure, every two or more adjacent device bonding areas are grouped by at least one bridging line therebetween to bridge the corresponding first bonding pad and the corresponding second bonding pad together, and the remaining first bonding pad and the remaining second pad are respectively electrically connected to an AC power supply through a plurality of external lead lines, so as to form a series loop serially connecting the device bounding areas inside each of the group.

According to an embodiment of the present disclosure, the first LED chips include a plurality of blue LED chips or a plurality of white LED chips.

According to an embodiment of the present disclosure, the second LED chips include a plurality of red LED chips.

According to an embodiment of the present disclosure, the first LED chips are serially connected in sequence at the common routes with a same polarity direction.

According to an embodiment of the present disclosure, the second LED chips are serially connected in sequence at the first routes and at the second routes with a same polarity direction.

An aspect of the present disclosure provides an illumination module including a substrate, a plurality of first light emitting diode (LED) chips and a plurality of second LED chips. The substrate has a plurality of device bonding areas, wherein each of the device bonding areas has multiple of sub-device bonding areas, and each of sub-device bonding areas has a first route, a second route, and a common route, and the first routes, the second routes and the common routes are designed as a bridge circuit. The first light emitting diode (LED) chips are located at the common routes and electrically connected in sequence. The second LED chips are located at the first routes and the second routes respectively and electrically connected in sequence.

According to an embodiment of the present disclosure, the first LED chips include a plurality of blue LED chips or a plurality of white LED chips.

According to an embodiment of the present disclosure, the second LED chips include a plurality of red LED chips.

According to an embodiment of the present disclosure, the illumination module further includes a plurality of Zener diode chips respectively disposed on the substrate, wherein the Zener diode chips are respectively located at the first routes or at the second routes.

According to an embodiment of the present disclosure, the illumination module further includes a plurality of first bonding pads and a plurality of second bonding pads, wherein each of the device bonding areas corresponds to a first bonding pad and a second bonding pad, and the first bonding pads and the second bonding pads are respectively located between the first routes and the second routes of the sub-device bonding areas and connected to the first routes and the second routes.

According to an embodiment of the present disclosure, the illumination module further includes a plurality of bridging lines respectively disposed between any two adjacent device bonding areas, and the bridging lines are extended from the second bonding pad inside one of the device bonding areas to the first bonding pad inside another one of the device bonding areas adjacent to the second bonding pad.

According to an embodiment of the present disclosure, the bridging lines respectively bridge the corresponding first bonding pads and the corresponding second bonding pads, and the remaining first bonding pad and the second bonding pad located at two ends are respectively electrically connected to an AC power supply through a plurality of external lead lines, so as to form a series loop serially connecting all of the device bonding areas.

According to an embodiment of the present disclosure, every two or more adjacent device bonding areas are grouped by at least one bridging line therebetween to bridge the corresponding first bonding pad and the corresponding second bonding pad together, and the remaining first bonding pad and the remaining second pad are respectively electrically connected to an AC power supply through a plurality of external lead lines, so as to form a series loop serially connecting the device bounding areas inside each of the group.

An aspect of the present disclosure provides an illumination module including a substrate, a plurality of blue light emitting diode (LED) chips and a plurality of red LED chips. The substrate has a plurality of first routes, a plurality of second routes, and a plurality of common routes. The blue light emitting diode (LED) chips are located at the common routes and electrically connected in sequence. The red LED chips are located at the first routes and the second routes respectively and electrically connected in sequence, and the first routes, the second routes and the common routes are designed as a bridge circuit.

In summary, since the LED chips according to embodiments of the present disclosure are disposed on the substrate in a chip on board (COB) type package, therefore the heat produced by the LED chips can be directly transferred to the substrate unimpeded by other films or structures. Consequently, the illumination module according to embodiments of the present disclosure may have a preferred heat dissipating capacity and a preferred light emitting efficiency. Moreover, embodiments of the present disclosure adopt different circuit loop designs using bridge circuits, bridging lines, and external lead lines so as to achieve switching between series and parallel coupling modes. Therefore, the illumination module according to embodiments of the present disclosure does not require an AC-DC converter embedded therein. Moreover, electronic components such as an inverter, a rectifier, a filter, or a voltage regulator are not required to control the illumination module with an AC power from an outlet. By contrast, compared with conventional techniques, the illumination module according to embodiments of the present disclosure can reduce a number of electronic components (e.g., inverters, rectifiers, filters, or voltage regulators) required, and thus the miniaturization of the illumination module can be readily achieved. Additionally, user convenience is enhanced while manufacturing costs are lowered.

In order to make the aforementioned and other features and advantages of the present disclosure more comprehensible, embodiments accompanying figures are described in detail below.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain the principles of the present disclosure.

FIG. 1 is a schematic view of an illumination module according to an embodiment of the present disclosure.

FIG. 2 is a partial enlarged view of the illumination module depicted in FIG. 1.

FIG. 3 is a circuit diagram of the illumination module depicted in FIG. 2.

FIG. 4 is a schematic cross-sectional view of the illumination module depicted in FIG. 2 along a line A-A′.

FIG. 5 is a schematic view of an illumination module according to another embodiment of the present disclosure.

### DESCRIPTION OF PREFERRED EMBODIMENTS

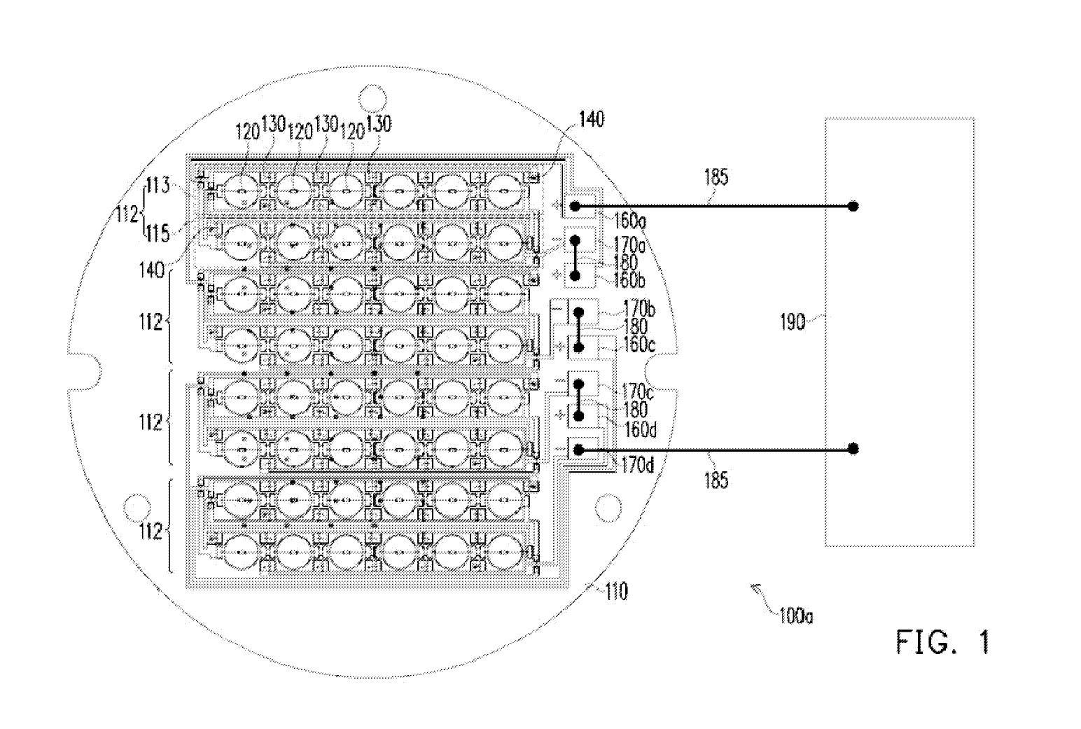

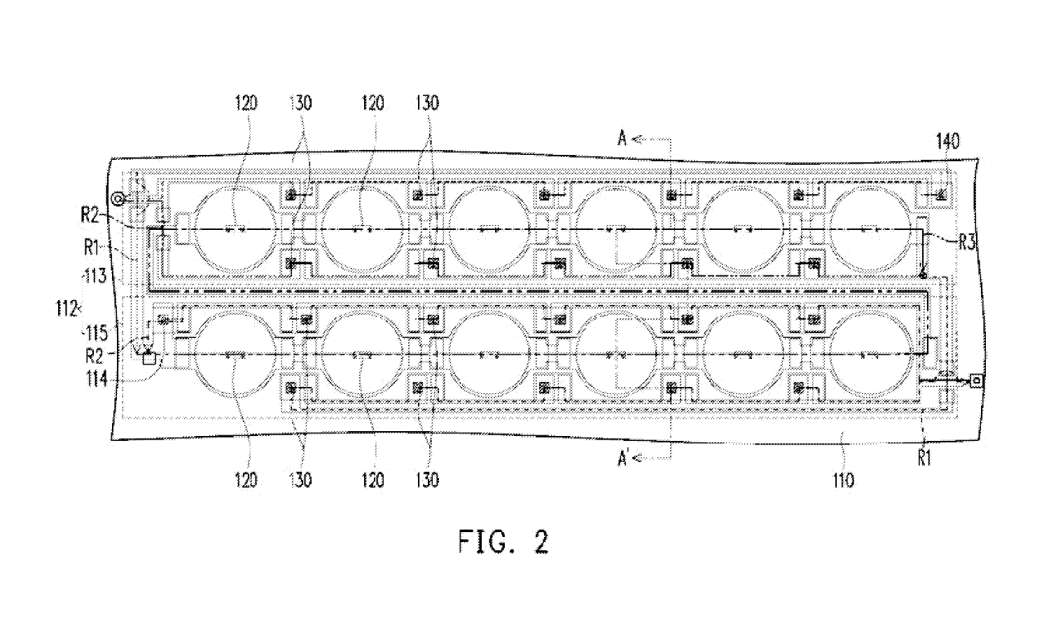

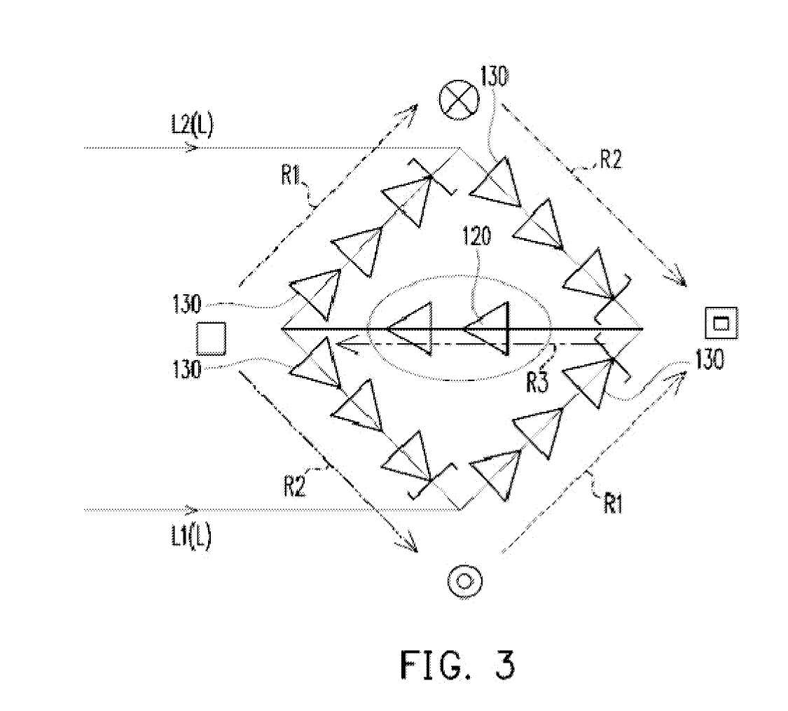

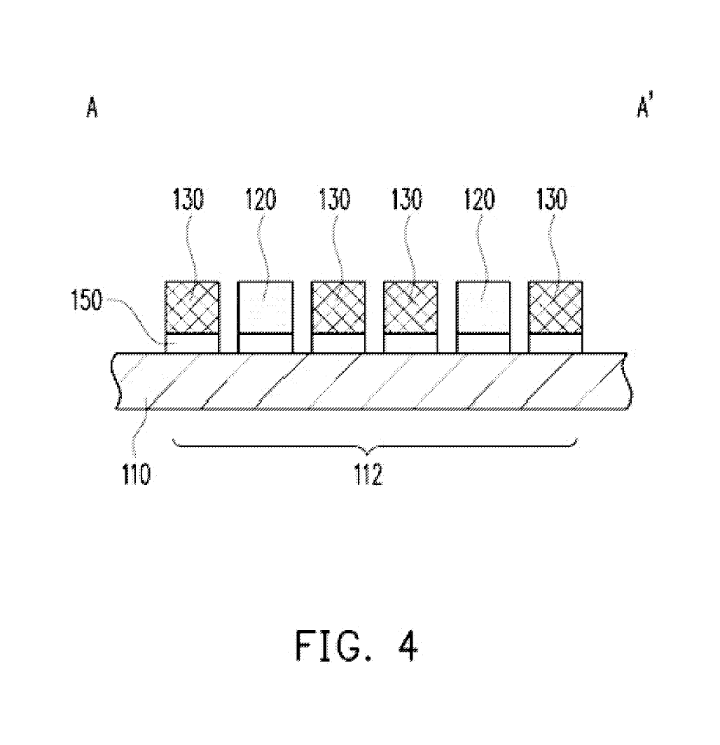

FIG. 1 is a schematic view of an illumination module according to an embodiment of the present disclosure. FIG. 2 is a partial enlarged view of the illumination module depicted in FIG. 1. FIG. 3 is a circuit diagram of the illumination module depicted in FIG. 2. FIG. 4 is a schematic cross-sectional view of the illumination module depicted in FIG. 2 along a line A-A′. Referring to FIGS. 1, 2, and 3 concurrently, in the present embodiment of the present disclosure, an illumination module 100a includes a substrate 110, a plurality of first LED chips 120, and a plurality of second LED chips 130.

More specifically, the substrate 110 includes a plurality of device bonding areas 112 (e.g., four device bonding areas 112 are schematically illustrated in FIG. 1), a plurality of first routes R1, a plurality of second routes R2, and a plurality of common routes R3. The substrate 110 is a circuit board, for example, and each of the device bonding areas 112 has two sub-device bonding areas 113 and 115. Each of the sub-device bonding areas 113 (or the sub-device bonding areas 115) has a first route R1, a second route R2, and a common route R3. The first routes R1 are respectively located around a periphery of each of the device bonding areas 112. The second routes R2 disposed inside two adjacent sub-device bonding areas 113 and 115 are adjacent to each other. The common routes R3 are located between the first routes R1 and the second routes R2.

The first LED chips 120 are arranged in an array on the substrate 110 and electrically connected thereto. Moreover, the first LED chips 120 are respectively located at the common routes R3 inside the device bonding areas 112, and the first LED chips 120 inside each of the device bonding areas 112 are electrically connected to each other. The second LED chips 130 are arranged in an array on the substrate 110 and electrically connected thereto. Moreover, the second LED chips 130 are respectively located at the first routes R1 and the second routes R2 inside the device bonding areas 112. The second LED chips 130 located at the first routes R1 inside each of the device bonding areas 112 are electrically connected to each other. The second LED chips 130 located at the second routes R2 inside each of the device bonding areas 112 are electrically connected to each other. Specifically, in the present embodiment, the second LED chips 130 located at the first routes R1 and the second routes R2 are respectively alternately arranged with the first LED chips 120 located at the common routes R3.

It should be noted that, in the present embodiment, the first LED chips 120 are, for example, a plurality of blue LED chips or a plurality of white LED chips. Moreover, the first LED chips 120 are serially connected in sequence at the common routes R3 with a same polarity direction. The second LED chips 130 are, for example, a plurality of red LED chips. Furthermore, the second LED chips 130 are serially connected in sequence at the first routes R1 and at the second routes R2 with a same polarity direction.

Furthermore, in order to prevent the first LED chips 120 and the second LED chips 130 from damage due to an abnormal voltage or a static discharge, the illumination module 100a according to the present embodiment may further include a plurality of Zener diode chips 140. The Zener diode chips 140 are respectively disposed inside the device bonding areas 112. Moreover, the Zener diode chips 140 are respectively located at the first routes R1 inside each of the first sub-device bonding areas 113 and at the second routes R2 inside each of the sub-device bonding areas 115. Accordingly, the first LED chips 120, the second LED chips 130, and the Zener diode chips 140 are connected in parallel, so as to prevent the first LED chips 120 and the second LED chips from damage due to an abnormal voltage or a static discharge. Additionally, it should be noted that, the afore-described disposition of the Zener diode chips 140 is merely exemplary and should not be construed as a limitation of the present disclosure.

Referring to FIG. 4, in the present embodiment, the illumination module 100a further includes an adhesive layer 150 disposed between the substrate 110 and the first LED chips 120, as well as between the substrate 110 and the second LED chips 130. Accordingly, the first LED chips 120 and the second LED chips 130 are tightly attached to the substrate 110 by the adhesive layer 150.

Since the first LED chips 120 and the second LED chips 130 according to the present embodiment are directly attached to the substrate 110 by the adhesive layer 150, namely the LED chips are packaged in a chip on board (COB) type package. Therefore, the heat produced by the first LED chips 120 and the second LED chips 130 can be directly transferred to the substrate 110 unimpeded by other films or structures. Consequently, the illumination module 100a according to the present embodiment may have a preferred heat dissipating capacity and a preferred light emitting efficiency. Generally speaking, in order to obtain a favorable heat dissipating property for the first LED chips 120 and the second LED chips 130, a metal core printed circuit board (MCPCB) having a preferred heat dissipating effect may be selected for the substrate 110. However, in other embodiments of the present disclosure, alternative types of circuit boards may be adopted, since the afore-described choice is merely exemplary and should not be construed as a limitation of the present disclosure.

Particularly, in the present embodiment, when an alternating current (AC) voltage L is applied to each of the device bond areas 112, the second LED chips 130 located at the first routes R1, the first LED chips 120 located at the common routes R3, and the second LED chips 130 located at the second routes R2 are sequentially lit according to a polarity of the AC voltage L (e.g., in accordance to a first AC voltage L1 that is a positive voltage, for example, or a second AC voltage L2 that is a negative voltage).

More specifically, referring to FIGS. 2 and 3, when the first AC voltage L1 (e.g., a positive voltage) is applied to each of the device bonding areas 112, the first LED chips 120 located at the common routes R3 and the second LED chips 130 located at the first routes R1 can be lit. On the other hand, when the second AC voltage L2 (e.g., a negative voltage) is applied to each of the device bonding areas 112, the first LED chips 120 located at the common routes R3 and the second LED chips 130 located at the second routes R2 can be lit. In other words, the first LED chips 120 located at the common routes R3 are continuously lit, whereas the second LED chips 130 located at the first routes R1 and the second routes R2 are not continuously lit. Moreover, since the second LED chips 130 surround the first LED chips 120, a color rendering index (CRI) and a light emitting efficiency of the illumination module 100a according to the present embodiment may be enhanced. The afore-described arrangement of the first LED chips 120 and the second LED chips 130, as well as the design of the first routes R1, the second routes R2, and the common routes R3 may be viewed as a bridge circuit design.

Furthermore, referring to FIG. 1, in the present embodiment, the illumination module 100a further includes a plurality of first bonding pads 160a-160d, a plurality of second bonding pads 170a-170d, a plurality of bridging lines 180, and a plurality of external lead lines 185. More specifically, each of the device bonding areas 112 corresponds to a first bonding pad 160a (or 160b, 160c, and 160d) and a second bonding pad 170a (or 170b, 170c, and 170d). Moreover, the first bonding pads 160a are respectively located between the first routes R1 and the second routes R2 of the sub-device bonding areas 113, for connecting the first routes R1 and the second routes R2 inside the sub-device bonding areas 113. The second bonding pads 170a are located between the first routes R1 and the second routes R2 of the sub-device bonding areas 115, for connecting the first routes R1 and the second routes R2 inside the sub-device bonding areas 115.

The bridging lines 180 are respectively disposed between any two adjacent device bonding areas 112, and the bridging lines 180 are extended from the second bonding pad 170a (or 170b, 170c, and 170d) inside one of the device bonding areas 112 to the first bonding pad 160b (or 160c and 160d) inside another one of the device bonding areas 112 adjacent to the second bonding pad 170a (or 170b, 170c, and 170d). The external lead lines 185 may be optionally electrically connected to the first bonding pads 160a-160d and the second bonding pads 170a-170d. Moreover, an AC voltage can be inputted from an AC power supply 190 through the external lead lines 185 to the device bonding areas 112 of the substrate 110, so as to form different circuit loops.

Two different embodiments are represented in the following to distinctly describe the designs of different loops formed by the illumination modules 100a and 100b through the bridging between the bridge circuit, the bridging lines 180, and the external lead lines 185.

Referring again to FIG. 1, the bridging lines 180 are respectively bridging the corresponding second bonding pad 170a and the first bonding pad 160b, the second bonding pad 170b and the first bonding pad 160c, and the second bonding pad 170c and the first bonding pad 160d. Moreover, the remaining first bonding pad 160a and the second bonding pad 170d located at the two ends are respectively electrically connected to the AC power supply 190 through the external lead lines 185, so as to form a series loop serially connecting all of the device bonding areas 112. Since only four device bonding areas 112 are schematically illustrated in FIG. 1, the series loop is a loop with four elements connected in series. That is to say, the illumination module 100a according to the present embodiment may form a loop with four elements serially connected through the bridging between the bridge circuit, the bridging lines 180, and the external lead lines 185.

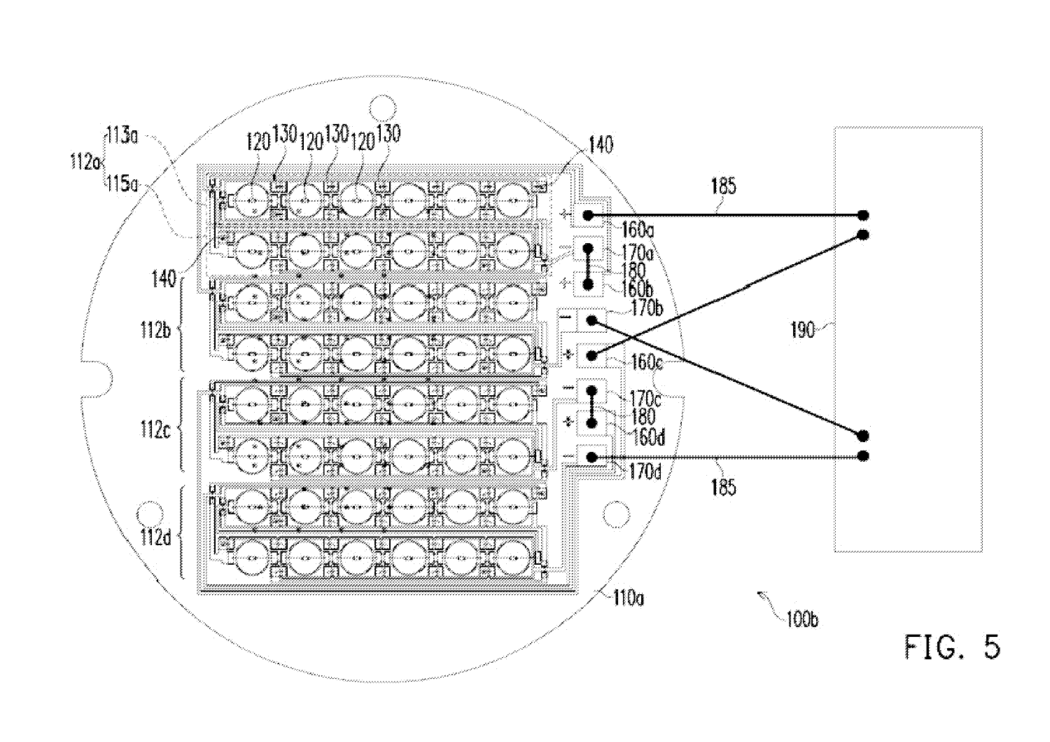

FIG. 5 is a schematic view of an illumination module according to another embodiment of the present disclosure. Referring to FIG. 5, in the present embodiment, a substrate 110a of an illumination module 100b depicted in FIG. 5 has four device bonding areas 112a-112d, wherein every two or more adjacent device bonding areas 112a and 112b (or device bonding areas 112c and 112d) forms a group. More specifically, inside the device bonding areas 112a and 112b, the bridging lines 180 bridge the corresponding second bonding pad 170a and the corresponding first bonding pad 160b. The remaining first bonding pad 160a and the second bonding pad 170b are respectively electrically connected to the AC power supply 190 through the external lead lines 185, so as to form a series loop serially connecting the device bonding areas 112a and 112b inside the group.

Similarly, inside the device bonding areas 112c and 112d, the bridging lines 180 bridge the corresponding second bonding pad 170c and the first bonding pad 160d. The remaining first bonding pad 160c and the second bonding pad 170d are respectively electrically connected to the AC power supply 190 through the external lead lines 185, so as to form a series loop serially connecting the device bonding areas 112c and 112d inside each group. In other words, the illumination module 100b according to the present embodiment may form a loop with two parallel series each composed of two serially connected elements through the bridging between the bridge circuit, the bridging lines 180, and the external lead lines 185.

That is to say, different designs of circuit loops may be produced for the illumination modules 100a and 100b of the present embodiment, according to different user requirements. Accordingly, the illumination modules 100a and 100b of the present embodiment do not require an AC-DC converter embedded therein. Moreover, electronic components such as an inverter, a rectifier, a filter, or a voltage regulator are not required to control the illumination modules 100a and 100b with an AC power from an outlet. By contrast, compared with conventional techniques, the illumination modules 100a and 100b according to the present embodiment can reduce the requirements of electronic components (e.g., inverters, rectifiers, filters, or voltage regulators), and thus the miniaturization of the illumination modules 100a and 100b can be readily achieved. Additionally, user convenience is enhanced and manufacturing costs lowered.

In view of the foregoing, since the LED chips according to embodiments of the present disclosure are disposed on the substrate in a chip on board (COB) type package, therefore the heat produced by the LED chips can be directly transferred to the substrate. Therefore, the backlight module according to embodiments of the present disclosure may have a preferred heat dissipating capacity and a preferred light emitting efficiency. Moreover, embodiments of the present disclosure adopt different circuit loop designs using bridge circuits, bridging lines, and external lead lines so as to achieve switching between series and parallel coupling modes, thereby reducing the need for an inverter or other electronic components. Therefore, the illumination module according to embodiments of the present disclosure can reduce the requirements of electronic components (e.g., inverters, rectifiers, filters, or voltage regulators), and thus the miniaturization of the illumination module can be readily achieved. Additionally, user convenience is enhanced and manufacturing costs lowered.

Although the present disclosure has been described with reference to the above embodiments, it will be apparent to one of the ordinary skill in the art that modifications to the described embodiment may be made without departing from the spirit of the present disclosure. Accordingly, the scope of the present disclosure will be defined by the attached claims not by the above detailed descriptions.

What is claimed is:

1. An illumination module charged by alternating current (AC) power, comprising:
a substrate having a plurality of device bonding areas, wherein each of the device bonding areas has two sub-device bonding areas, and each of the sub-device bonding areas has a first route, a second route, and a common route, and the first routes surround the outer peripheries of each device bonding areas, and the second routes are located between the two sub-device bonding areas, and the common routes are located between the first and second routes;
a plurality of first light emitting diode (LED) chips located at the common routes and electrically connected to each other; and
a plurality of second LED chips located at the first routes and the second routes respectively are electrically connected to each other.

2. The illumination module charged by alternating current (AC) power according to claim 1, further comprising a plurality of Zener diode chips respectively disposed inside the device bonding areas, wherein the Zener diode chips are respectively located at the first routes or at the second routes inside the sub-device bonding areas.

3. The illumination module charged by alternating current (AC) power according to claim 1, further comprising an adhesive layer disposed between the substrate and the first LED chips and between the substrate and the second LED chips.

4. The illumination module charged by alternating current (AC) power according to claim 1, further comprising a plurality of first bonding pads and a plurality of second bonding pads, wherein each of the device bonding areas corresponds to a first bonding pad and a second bonding pad, and the first bonding pads and the second bonding pads are respectively located between the first routes and the second routes of the sub-device bonding areas and connected to the first routes and the second routes.

5. The illumination module charged by alternating current (AC) power according to claim 4, further comprising a plurality of bridging lines respectively disposed between any two adjacent device bonding areas, and the bridging lines are extended from the second bonding pad inside one of the device bonding areas to the first bonding pad inside another one of the device bonding areas adjacent to the second bonding pad.

6. The illumination module charged by alternating current (AC) power according to claim 5, wherein the bridging lines respectively bridge the corresponding first bonding pads and the corresponding second bonding pads, and the remaining first bonding pad and the second bonding pad located at two ends are respectively electrically connected to an AC power supply through a plurality of external lead lines, so as to form a series loop serially connecting all of the device bonding areas.

7. The illumination module charged by alternating current (AC) power according to claim 5, wherein every two or more adjacent device bonding areas are grouped by at least one bridging line therebetween to bridge the corresponding first bonding pad and the corresponding second bonding pad together, and the remaining first bonding pad and the remaining second pad are respectively electrically connected to an AC power supply through a plurality of external lead lines, so as to form a series loop serially connecting the device bounding areas inside each of the group.

8. The illumination module charged by alternating current (AC) power according to claim 1, wherein the first LED chips comprise a plurality of blue LED chips or a plurality of white LED chips.

9. The illumination module charged by alternating current (AC) power according to claim 1, wherein the second LED chips comprise a plurality of red LED chips.

10. The illumination module charged by alternating current (AC) power according to claim 1, wherein the first LED chips are serially connected in sequence at the common routes with a same polarity direction.

11. The illumination module charged by alternating current (AC) power according to claim 1, wherein the second LED chips are serially connected in sequence at the first routes and at the second routes with a same polarity direction.

12. An illumination module, comprising:
a substrate having a plurality of device bonding areas, wherein each of the device bonding areas has multiple of sub-device bonding areas, and each of sub-device bonding areas has a first route, a second route, and a common route, and the first routes, the second routes and the common routes are designed as a bridge circuit;
a plurality of first light emitting diode (LED) chips located at the common routes and electrically connected in sequence; and
a plurality of second LED chips located at the first routes and the second routes respectively and electrically connected in sequence.

13. The illumination module according to claim 12, wherein the first LED chips comprise a plurality of blue LED chips or a plurality of white LED chips.

14. The illumination module according to claim 12, wherein the second LED chips comprise a plurality of red LED chips.

15. The illumination module according to claim 12, further comprising a plurality of Zener diode chips respectively disposed on the substrate, wherein the Zener diode chips are respectively located at the first routes or at the second routes.

16. The illumination module according to claim 12, further comprising a plurality of first bonding pads and a plurality of second bonding pads, wherein each of the device bonding areas corresponds to a first bonding pad and a second bonding pad, and the first bonding pads and the second bonding pads are respectively located between the first routes and the second routes of the sub-device bonding areas and connected to the first routes and the second routes.

17. The illumination module according to claim 16, further comprising a plurality of bridging lines respectively disposed between any two adjacent device bonding areas, and the bridging lines are extended from the second bonding pad inside one of the device bonding areas to the first bonding pad inside another one of the device bonding areas adjacent to the second bonding pad.

18. The illumination module according to claim 17, wherein the bridging lines respectively bridge the corresponding first bonding pads and the corresponding second bonding pads, and the remaining first bonding pad and the second bonding pad located at two ends are respectively electrically connected to an AC power supply through a plurality of external lead lines, so as to form a series loop serially connecting all of the device bonding areas.

19. The illumination module according to claim 17, wherein every two or more adjacent device bonding areas are grouped by at least one bridging line therebetween to bridge the corresponding first bonding pad and the corresponding second bonding pad together, and the remaining first bonding pad and the remaining second pad are respectively electrically connected to an AC power supply through a plurality of external lead lines, so as to form a series loop serially connecting the device bounding areas inside each of the group.

20. An illumination module, comprising:
a substrate having a plurality of first routes, a plurality of second routes, and a plurality of common routes;
a plurality of blue light emitting diode (LED) chips located at the common routes and electrically connected in sequence; and
a plurality of red LED chips located at the first routes and the second routes respectively and electrically connected in sequence;
wherein the first routes, second routes, and the common routes are designed as a bridge circuit.
